(19) United States
(12) Patent Application Publication
(10) Pub. No.: US 2004/0241582 A1
(43) Pub. Date: Dec. 2, 2004

(54) Method for high resolution patterning using low-energy electron beam, process for preparing nano device using the method

(76) Inventors: Joon Won Park, Kyungsangbuk-do (KR); Young-Hye La, Kyungsangbuk-do (KR); Bongsoo Kim, Kyungsangbuk-do (KR); Tai-Hee Kang, Kyungsangbuk-do (KR); Ki-Jeong Kim, Kyungsangbuk-do (KR)

Correspondence Address: ROTHWELL, FIGG, ERNST & MANBECK, P.C., 1425 K STREET, N.W., SUITE 800, WASHINGTON, DC, 20005, US

(21) Appl. No.: 10/489,349

(22) PCT Filed: Sep. 12, 2002
(86) PCT No.: PCT/KR02/01715

(30) Foreign Application Priority Data
Sep. 12, 2001 (KR) 2001-56223

(51) Int. Cl. G03F 7/00

(52) U.S. Cl. 430/296; 430/311; 430/322

(57) ABSTRACT

A method for high resolution patterming using low-energy electron beam and a method for manufacturing a nano device using the high resolution pattern are provided. The method involves forming an aromatic imine molecular layer having a substituted or unsubstituted terminal ring on a substrate; selectively changing imine bonds structurally in the aromatic imine molecular layer, and hydrolyzing the aromatic imine molecular layer.

### BACKGROUND OF THE INVENTION

1. Field of the Invention

The present invention relates to a method for high resolution patterning and a process for manufacturing a nano device using the high resolution pattern, and more particularly, to a method for micro- or nano-scale high resolution patterning within a short period of time, and a nano device formed using the method.

2. Description of the Related Art

With recent advances in the semiconductor industry and the need for highly-integrated semiconductor devices, nano- or micro-fabrication technologies for minute patterning attract more and more attention.

As is expected by many experts that nanotechnology will be one of the leading technologies in the 21st century, nano-pattern fabrication is an essential technology of the highest priority in minute-circuit processing for large-capacity semiconductor devices. In addition, nano-patterning technology has wide applications, for example, in the bioengineering related fields and for biosensors, so its consequence becomes great.

So far, surface patterning has been achieved by photolithography employing deep UV radiation and polymer-photoresists, leading to stunning advances in the semiconductor industry.

Pattern resolution in photolithography is determined according to Rayleigh's equation, R=k₁λ/NA, where R denotes resolution, λ denotes wavelength, k₁ is a constant, and NA denotes the numerical aperture of a lens system. A shorter wavelength of light used results in higher resolution and smaller patterns. A pattern resolution on the order of 500 nm, achieved in the early 1980s by G-line (436 nm) exposure systems using high-pressure mercury lamps, has markedly been reduced to 180 nm recently by the use of 248-nm KrF eximer laser exposure technology, thereby realizing the production of 1-Gb memory semiconductors (Solid State Technol., January 2000). However, due to the limitations in the wavelength of usable light, equipment and technology requirements, and the resolution of polymeric photoresist used, it is difficult to form nano-scale high-resolution patterns with this method.

For higher pattern resolutions, many attempts have been made since 1990, for example, using self-assembled monolayers as a new photoresist, instead of polymers used in conventional photolithography, and using light of a short wavelength. In addition, new patterning technologies for self-assembled monolayers, for example, soft lithography or scanning probe lithography using tips of AFM and STM have been introduced.

In the early 1990s, Whitesides, a professor at Harvard University, developed surface patterning techniques using flexible organic substances, i.e., alkyl compounds having functional groups and polymers, not using light or high energy particles, and termed these patternings collectively as “soft lithography” (Appl. Phys. Lett., 1993, 63, 2002). A representative example is concerned with microcontact printing (μCP) involving stamping surfactant molecules, for example, alkanethiol, in a surface area with a polydimethylsiloxane (PDMS) elastomer stamp to form patterns of self-assembled monolayers only on the stamping area. This microcontact printing enables speedy and economical consecutive patternings. However, this technique has some problems to be solved, such as inaccurate registration (<1 μm) due to the deformation of an elastomeric stamp, incompatibility with current integrated circuit (IC) processes, etc.

Recently, Mirkin et al. have developed “dip-pen” nanolithography (DPN) which uses an AFM tip as a “nib”, a solid substrate (for example, Au) as “paper”, and molecules with a chemical affinity for the solid substrate as “ink”. Molecules are delivered from the AFM tip to a solid substrate of interest via capillary transport (Science, 1999, 283, 661). Due to the use of elaborately formed sharp tips, dip-pen nanolithography offers a high-resolution, nano-scale pattern of about 5 nm. However, its time-consuming serial pattern drawing processes limit commercialization through mass production.

Lercel Group of Cornel University suggested the use of a focused electron beam as a new light source for surface patterning. In particular, octadecylsiloxane self-assembled monolayers were irradiated with a focused electron beam of an energy of 20 keV (<35.7 mC/cm²) to randomly cleave bonds in the monolayer, and the cleaved bonds are separated out by washing with a UV/ozone cleaner, thereby resulting in a spot pattern having a minimum feature size of 5 nm on a silica surface (J. Vac. Sci., Technol. B, 1996, 14, 4086). Although achieving a high resolution pattern on the order of a few nanometers as well as avoiding the problems arising from light diffractions, a time-consuming sequential manner of the patterning processes is still serious limitation of this lithographic method. Furthermore, the need for costly electron beam focusing instruments makes the application of this technique impractical.

### SUMMARY OF THE INVENTION

Therefore, the present invention provides a method for forming a high resolution pattern of a desired shape within a short period of time.

The present invention provides a substrate with a high resolution pattern.

The present invention also provides a method for manufacturing a high performance and miniaturized semiconductor device using the high resolution pattern.

The present invention also provides a biochip using the high resolution pattern.

The present invention provides a method for high resolution patterning, comprising: (a) forming an aromatic imine monolayer having a substituted or unsubstituted terminal ring on a substrate; (b) selectively transforming imine bonds structurally in the aromatic imine monolayer; and (c) hydrolyzing the aromatic imine monolayer.

In an embodiment of the method according to the present invention, (a) forming the aromatic imine molecular layer on the substrate may comprise forming a self-assembled aminosilylated- or aminothiolated monolayers on the substrate and processing the surface of the aminosilylated or aminothiolated monolayers with an aromatic aldehyde having a substituted or unsubstituted terminal ring.

The aromatic aldehyde with the substituted or unsubstituted terminal ring may be a conjugated or non-conjugated aromatic aldehyde.

The non-conjugated aromatic aldehyde with the substituted or unsubstituted terminal ring may be a compound of formula (1) below:

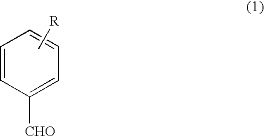

where R is hydrogen atom, a substituted or unsubstituted C₁-C₂₀ alkyl group, a substituted or unsubstituted C₁-C₂₀ alkoxy group, or a substituted or unsubstituted C₆-C₃₀ aryl group.

The conjugated aromatic aldehyde with the substituted or unsubstituted terminal ring may be a compound of formula (2), (3), or (4) below:

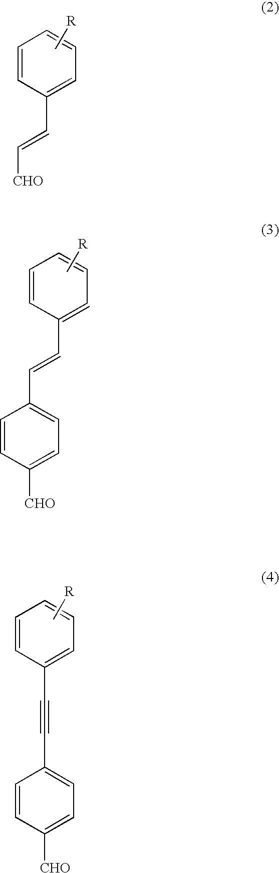

In formulae (2), (3), and (4) above, R is hydrogen atom, a substituted or unsubstituted C₁-C₂₀ alkyl group, a substituted or unsubstituted C₁-C₂₀ alkoxy group, or a substituted or unsubstituted C₆-C₃₀ aryl group.

The substrate used in the present invention may be a silica or gold substrate.

In another embodiment of the high resolution patterning method according to the present invention, (b) selectively transforming imine groups structurally in the aromatic imine molecular layer may comprise exposing the substrate through a photomask to a low-energy electron beam. In this case, the low-energy electron beam may have an energy level below 5,000 eV.

The present invention also provides a substrate with a high resolution pattern, the substrate comprising a base plate and a surface layer on the base plate, wherein the surface layer includes a hydrophilic amine molecular layer in a region and a hydrophobic aromatic imine molecular layer in the other region which form the high resolution pattern together.

The present invention also provides a method for manufacturing a semiconductor device with a high resolution pattern, the method comprising: coating a diblock copolymer onto a substrate having a high resolution pattern formed using the above-described patterning method; and annealing and etching the substrate coated with the diblock copolymer. The diblock copolymer may be poly(stylene-block-methylmethacrylate)

The present invention also provides a biochip comprising a substrate with a high resolution pattern formed using the above-described patterning method and biomolecules immobilized on amine groups in the hydrophilic amine molecular layer. The biomolecules may be proteins, DNA, or RNA.

Hereinafter, the present invention will be described below in detail. According to the present invention, after forming an aromatic imine monolayer by reacting amine groups in an aminosilylated or aminothiolated monolayers previously formed on the substrate with an aromatic aldehyde compound having various substitutents, the imine bonds in the aromatic imine molecular layer are selectively transformed into hydrophobic chemical moieties resistant to hydrolysis by low-energy electron beam irradiation. A non-irradiated region of the aromatic imine molecular layer becomes to have the hydrophilic amine groups on the surface through hydrolysis. As a result, a high resolution pattern of hydrophobic and hydrophilic regions having a height difference equal to the dimension of the terminal aromatic ring in the molecular layer.

The aromatic aldehyde capable of forming imine bonds through reactions with the amine groups on the molecular layer may be a substituted benzaldehyde having formula (1) above or a conjugated aromatic aldehyde.

Suitable conjugated aromatic aldehydes include any aldehyde compound capable of forming an imine bond through condensation with the surface amine group. However, the compounds having formulae (2), (3), and (4) above capable of binding to the surface amine group at a high density and inducing a great pattern height difference after the hydrolysis are preferred.

As described above, the amine groups in the aminosilylated or aminothiolated monolayers on the surface of a substrate are reacted with the aromatic aldehyde compound by heating in ethanolic solution of an under an inert gas atmosphere, so that the aromatic imine molecular layer is formed on the substrate.

When the aromatic imine monolayer is heated in pure deionized water, imine bonds are hydrolyzed to separate the aromatic aldehyde from the amino silane molecular or amino thiol molecular layer on the substrate. As a result, the hydrophilic amine groups are restored on the surface of the substrate.

However, once the aromatic imine molecular layer is irradiated with a low-energy electron beam of 5,000 eV or less, the imine bond structurally transforms into non-hydrolyzable chemical species, thereby resulting in a new molecular layer having a hydrophobic region.

As described above, when low-energy electron beam irradiation onto the aromatic imine monolayer through an appropriately designed photomask is followed by hydrolysis in deionized water, an irradiated region of the molecular layer that is not hydrolyzed becomes to have a hydrophobic surface having the aromatic ring, whereas a non-irradiated region of the molecular layer where the imine groups are hydrolyzed becomes to have a hydrophilic surface having the amine group. As a result, a desired high-resolution pattern of alternate hydrophilic and hydrophobic regions can be formed on the surface of the substrate.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a method according to the present invention for forming on a silica substrate an aromatic imine monolayer that is likely to occur selective chemical transformation by low-energy electron beam irradiation;

FIG. 2 illustrates a method according to the present invention for forming on a gold substrate an aromatic imine monolayer that is likely to occur selective chemical transformation by low-energy electron beam irradiation;

FIG. 3 illustrates a process for high resolution patterning according to the present invention into the aromatic imine monolayer using a photomask;

FIG. 4 is an atomic force microscopic photograph at a scale of 10 μm×10 μm of a pattern formed on a substrate in Example 1 according to the present invention; and

FIG. 5 is an atomic force microscopic photograph at a scale of 80 μm×80 μm of the pattern formed on the substrate in Example 1 according to the present invention.

### DETAILED DESCRIPTION OF THE INVENTION

Hereinafter, a method for forming a micro- or nano-scale high resolution pattern on a substrate according to the present invention will be described with reference to the appended drawings.

Initially, a method for forming an aromatic imine monolayer using aminosilylated substrates will be described. A substrate on which the aromatic imine molecular layer will be formed is washed and dried. The clean substrate was immersed into a solution (20 mL) containing a silane coupling agents under nitrogen atmosphere, and placed in the solution for a predetermined period of time. Any amino silane compound producing no acidic byproduct, for example, (3-aminopropyl)diethoxymethylsilane, may be used without limitations. An example of a solvent for dissolving the amino silane compound may be toluene. Any kind of substrate, for example, a silica substrate, a gold substrate, etc., may be used in the present invention without limitations. When a gold substrate is used, it is preferable to treat the gold substrate with an alkane thiol compound having an amine group at its terminal.

When the above aminosilylateion is completed, the substrate is washed with a solvent and dried.

The amino-silylated substrate is immersed and heated in a ethanolic solution of an aromatic aldehyde compound under an inert gas atmosphere. The heating temperature may range from 20° C. to 100° C., and the heating time may range from 1 hour to 20 hours. After the reaction is completed, the substrate is washed with an organic solvent.

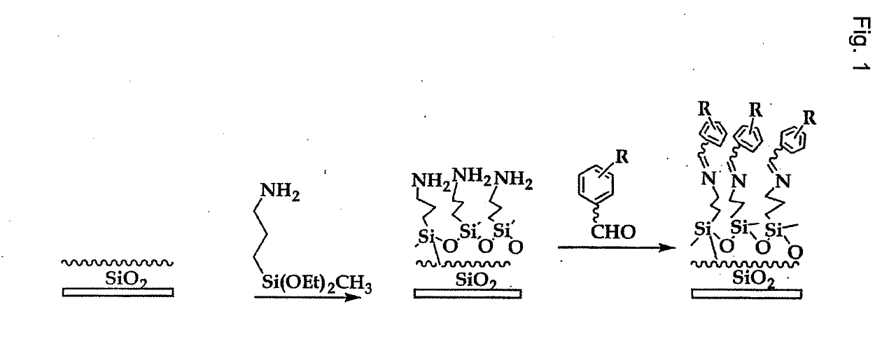

Through the above-described processes a substrate with the aromatic imine molecular layer, as shown in FIG. 1, can be obtained.

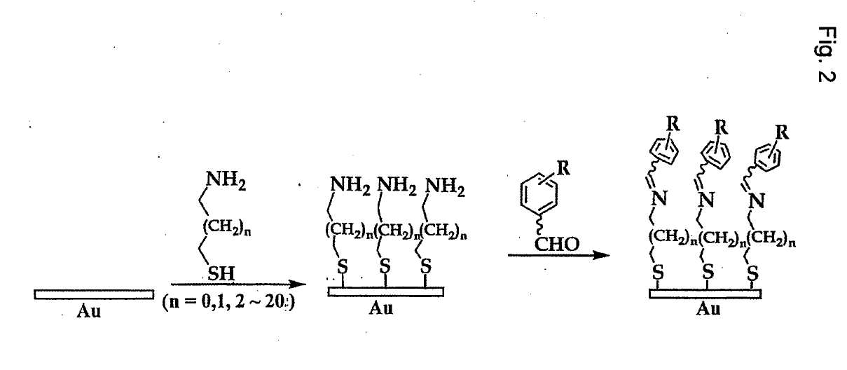

Another embodiment of a substrate with an aromatic imine molecular layer according to the present invention is illustrated in FIG. 2. The substrate of FIG. 2 is prepared in a similar manner as in the previous embodiment described with reference to FIG. 1, except that a gold substrate and an amino thiol compound are used instead of the silica substrate and the amino silane compound, respectively. An example of the amino thiol compound used in the present embodiment to form a monomolecular layer may be 3-aminopropanethiol. Ethanol may be used as a solvent for dissolving the amino thiol compound.

A substrate with an aromatic imine molecular layer as shown in FIGS. 1 and 2 is dried in a vacuum and fixed to a metallic sample holder. A photomask having a desired feature size and shape is placed on the substrate with a separation gap of about 1-10 μm. A smaller separation gap between the photomask and the substrate is more preferred. However, if the separation gap between the photomask and the substrate is less than 1 μm, the surface of the substrate may be unnecessarily contaminated, and the photomask is highly likely to be broken.

The substrate with the aromatic imine molecular layer fixed to the sample holder and covered with the photomask is placed into an ultra-high vacuum chamber. When the ultra high vacuum chamber is evacuated to 10⁻⁸ torr or less, a low-energy electron beam is perpendicularly radiated onto the surface of the substrate. The low-energy electron beam may have a range of energy level from a few eV to 5,000 eV. A larger size of the low-energy electron beam radiating a wide region, not being focused onto a particular region, is preferred. If the energy level of the electron beam exceeds the above range, undesirably, the organic molecular layer is indiscriminately destroyed.

The duration of low-energy electron beam irradiation is determined to be long enough for the imine group of a region to be chemically transformed. If an electron beam of 500 eV is radiated onto a 5 mm×5 mm region at a beam current of 0.08 A, it is enough to radiate the electron beam for about 8 minutes, which is equivalent to a dosage of 0.153 mC/cm². Compared with the patterning of alkylsilane self-assembled monolayers using a focused electron beam of 20 keV at 35.7 mC/cm² by Lercel Group, the dosage of electron beam is lower than by no less than 200 times. As such, a patterning system according to the present invention uses a low-energy electron beam and can pattern a larger area at one irradiation with a lower dosage of electron beam than conventional surface pattering systems using electron beams, so that a pattern of a desired shape can be efficiently patterned within a short period of time.

After the substrate with the aromatic imine monolayer exposed to the electron beams is drawn out of the ultra-high vacuum chamber, the substrate is immersed in pure deionized water and hydrolyzed at a temperature of 20-80° C. for, preferably, about 1-10 hours. The substrate after the hydrolysis is washed with an organic solvent and dried in a vacuum.

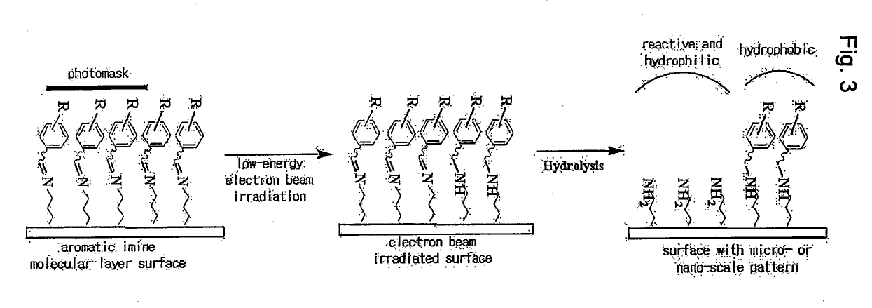

Through the above-described processes, a pattern of an organic molecular layer can be formed on the substrate, as shown in FIG. 3.

Referring to FIG. 3. in an electron beam irradiated region of the organic molecular layer, the imine bond is chemically transformed to be resistant to hydrolysis, thereby resulting in a hydrophobic surface having the aromatic ring. In a non-irradiated region of the organic molecular layer, the imine bond is cleaved by hydrolysis so that the hydrophilic amine groups are generated on the surface of the substrate. As a result, the irradiated and non-irradiated regions of the organic molecular layer pattern have a height difference equal to the dimension of the aromatic ring and can be visualized using atomic force microscopy (AFM).

A substrate with a micro- or nano-scale pattern according to the present invention can be used as a base substrate in manufacturing highly-integrated semiconductor circuits. In particular, when the micro- or nano-scale pattern of alternate hydrophobic and hydrophilic regions on the substrate is coated with a diblock copolymer, the height to which the diblock copolymer piles up differs by hundreds of nanometers between the separate hydrophobic and hydrophilic regions. When the substrate is immersed in an appropriate etchant, the high and low regions on the substrate are etched to different degrees, thereby transferring the micro- or nano-scale pattern into the substrate.

In particular, a diblock copolymer, for example, poly(styrene-block-polymethylmethacrylate), is coated onto the substrate with the high resolution pattern formed according to the present invention in a planar structure using, for example, spin coating. On the hydrophilic region of the substrate, polymethylmethacrylate (PMMA) is first arranged, and polystylene (PS), PS, PMMA, PMMA and PS are sequentially piled thereon, with the upper and outermost layer of PS having a low surface free energy, leading to an asymmetric wetting of the surface. Meanwhile, on the hydrophobic region of the substrate, PS is first arranged, and PMMA, PMMA, and PS are sequentially piled thereon, leading to a symmetric wetting of the surface.

When the substrate with the diblock copolymer layer is thermally treated at a high temperature, a molecular rearrangement occurs, and the symmetric wetting and asymmetric wetting regions become to have a quantized thickness of nL₀ and (n+½)L₀, respectively, wherein L₀ represents the thickness of a repeating unit, i.e., PS-PMMA, in the planar layer structure. In a region where the initial thickness is thinner than a quantized thickness after the thermal treatment, a hole is generated, while, in a region where the initial thickness is thicker than a quantized thickness after the thermal treatment, an island is formed. In result, the height contrast of the pattern is amplified.

When the substrate that has been thermally treated is subject to etching, a portion of the organic molecular layer on the surface of the substrate is removed to provide a semiconductor device with a micro- or nano-scale pattern. Types of etching which can be used include any common etching applied in the manufacture of semiconductor devices, for example, using a mixture of KCN and KOH solutions or a HF solution as an etchant.

A semiconductor device manufactured with a nano-patterning system according to the present invention as described above can overcome a feature size limit of 130 nm(or 90 nm), which is known to be the highest resolution that can be achieved using currently practical semiconductor manufacturing processes.

Since a micro- or nano-scale high resolution pattern according to the present invention has a hydrophilic portion with amine groups that can readily bind to enzymes or other functional substances, it can be applied to biosensors and various material-related fields. In particular, since the hydrophilicity and hydrophobicity of the pattern can be easily controlled on a micro- or nano-scale, the advantage of the high resolution pattern is the greatest when used for high density protein chips.

In a micro- or nano-scale high resolution pattern formed by the method according to the present invention, a region of highly reactive and hydrophilic amine groups serves as a reaction site to which biomolecules, such as proteins, DNA, or RNA can selectively bind. Also, a hydrophobic region of the high resolution pattern, which is alternated with the hydrophilic region, serves as a barrier for different kinds of biomolecules to diffuse without being mixed. Therefore, a micro- or nano-scale high resolution pattern formed according to the present invention can be applied to a surface of a substrate in order to form an array of various kinds of biomolecules on the surface through biomolecular interactions. Therefore, the micro- or nano-scale high resolution pattern according to the present invention is considered to greatly contribute to the production of high-integrated, high-throughput, miniature biochips.

In general, biochips are manufactured by immobilizing biomolecules on a substrate directly or via linker molecules. For example, a protein chip with antibody molecules can be manufactured by immobilizing the antibody molecules on a solid substrate through chemical interactions with amine groups previously attached to the surface of the solid substrate.

In the compounds of formulae (1), (2), (3), and (4) used in the present invention, suitable alkyl groups for substitutent R include straight or branched alkyl groups having 1-12 carbon atoms, preferably, 1-20 carbon atoms, and more preferably, 1-6 carbon atoms. Examples of such alkyl groups include methyl, ethyl, n-propyl, isopropyl, n-butyl, isobutyl, sec-butyl, t-butyl, pentyl, iso-amyl, hexyl, heptyl, octyl, nonyl, decyl, dodecyl, etc. Alternatively, at least one hydrogen atom in the alkyl group may be substituted with halogen group atom, a hydroxy group, a cyano group, or an amino group.

In the above compounds used in the present invention, the aryl group for substitutent R, alone or in combination, means a C₆-C₃₀ carbocyclic system having at least one ring, wherein such rings may be attached together in a pendent manner or may be fused. The term “aryl” embraces aromatic radicals such as phenyl, naphthyl, tetrahydronaphthyl, indane, biphenyl and the like, in which the preferable one is phenyl and naphthyl. The aryl group may have a substituent such as hydroxy, halide, haloalkyl, cyano, alkoxy, and lower alkylamino. Alternatively, at least one hydrogen atom of the acryl group may be substituted with halogen group, a hydroxy group, a cyano group, or an amino group.

In the above compounds used in the present invention, the alkoxy group for substitutent R includes an oxygen-containing straight or branched alkoxy radical having 1-20 carbon atoms, in which lower alkoxy radicals having 1-6 carbon atoms are more preferred. Examples of such alkoxy radicals include methoxy, ethoxy, propoxy, butoxy, t-butoxy, and the like. Lower alkoxy radicals having 1-3 carbon atoms are most preferred. The alkoxy radical may include haloalkoxy radicals with at least one halo-substituent selected from the group consisting of fluoro-, chloro-, and bromo-substituents, in which the preferable one is lower haloalkoxy radicals having 1-3 carbon atoms. Examples of such haloalkoxy radicals include fluoromethoxy, chloromethoxy, trifluoromethoxy, trifluoroethoxy, fluoroethoxy, fluoropropoxy, and the like.

The present invention will be described more fully with reference to the accompanying drawings, in which examples of the invention are shown. This invention may, however, be embodied in many different forms and should not be construed as being limited to the examples set fourth herein; rather these examples are provided so that this disclosure will be thorough and complete, and will fully convey the concept of the invention to those skilled in the art.

### EXAMPLE 1

Initially, a cleaned silica substrate was dried in a vacuum of about 20 mtorr. A round-bottom flask was charged with a solution of (3-aminopropyl)diethoxymethylsilane in toluene solvent (10⁻³M) under a nitrogen atmosphere. The dried silica substrate was immersed in that solution and reacted at room temperature for silanization.

After the silylation was completed, the substrate was washed with toluene, dried in an oven at 120° C. for 30 minutes, and cooled to room temperature. The cooled substrate was washed by ultrasonication in toluene, a solvent mixture of toluene and methanol in 1:1 by volume, and then methanol for 3 minutes each, and dried in a vacuum.

Next, the amino-silylated silica substrate was immersed in a solution of 0.2 mL of benzaldehyde in 25 mL of ethanol for 6 hours in a nitrogen atmosphere for condensation. At this time, the reaction temperature was maintained at 50° C.

The substrate after the reaction was washed with excess methanol and by ultrasonication in methanol and then acetone for 1 minute each, and dried in a vacuum.

The resulting benzealdimine molecular layer on the silica substrate was cut to a size of 1 cm×1 cm, fixed to an aluminum sample holder, covered with a photomask with a separation gap of 5 μm between the molecular layer and the photomask, and placed into a ultra-high vacuum chamber. When the ultra-high vacuum chamber was evacuated to 10⁻⁸ torr or less, an electron beam of 500 eV was perpendicularly radiated onto the substrate for 8 minutes (equivalent to a dose of 0.153 mC/cm²). The photomask used was a transmission electron microscopic (TEM) grid of a 1000-mesh size (G-1000HS, Energy Beam Sciences Inc.) The electron beam irradiation was performed using a LEG63 electron gun system (VG Microtech. Co.).

After being drawn out of the ultra-high vacuum chamber, the substrate was immersed in a mixture of 3 mL of pure deionized water and 1 mL of ethanol at 50° C. for 6 hours for hydrolysis. The substrate after the hydrolysis was washed by ultrasonication in a mixture of deionized water and ethanol and then acetone for 3 minutes each, and dried in a vacuum.

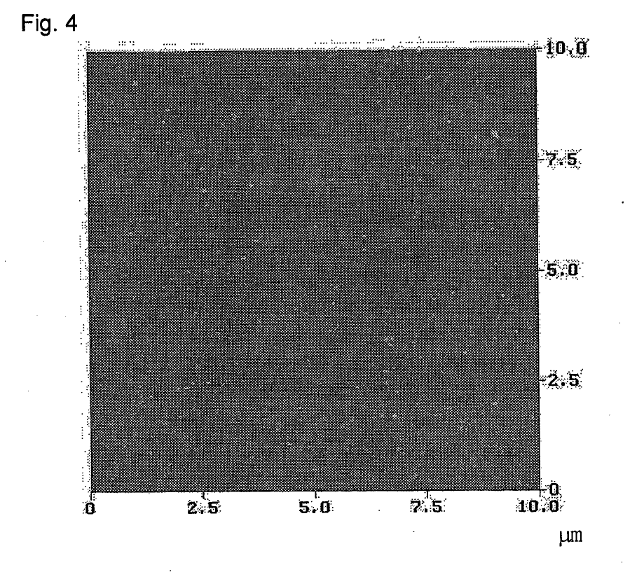

The resulting pattern on the substrate was confined using atomic force microscopy. The result is shown in FIG. 4.

### EXAMPLE 2

A substrate with a pattern was manufactured in the same manner as in Example 1, except that a gold substrate instead of the silica substrate and 3-aminopropanethiol instead of the (3-aminopropyl) diethoxymethylsilane were used for amino-thiolation. A cleaned gold substrate was immersed in a solution of 3-aminopropanethiol in ethanol (10 mM) and reacted for 3 hours in a nitrogen atmosphere for the amino-thiolation. The substrate after the amino-thiolation was washed with an organic solvent and dried in a vacuum.

### EXAMPLE 3

An aromatic imine molecular layer was formed on the substrate in the same manner as in Example 1, except that cinnamaldehyde instead of the benzaldehyde was used. In patterning, an electron beam of 500 eV was radiated onto the substrate at a dose of 0.153 mC/cm². Hydrolysis was carried out according to Example 1.

### EXAMPLE 4

A 2% diluted solution by weight of a symmetric poly(stylene-block-methylmethacrylate) copolymer (available from Polymer Source Inc.) in toluene was coated onto the silica substrate with the pattern manufactured in Example 1 using spin coating at 2,500-3,000 rpm. The resulting polymer thin film was thermally treated in a vacuum oven at 180° C. for 24 hours. The substrate after the thermal treatment was immersed in an alkaline solution of 0.01 M KCN and 2M KOH containing CN⁻ ions and stirred continuously to manufacture a semiconductor device with a nano-scale pattern.

### EXAMPLE 5

The silica substrate with the pattern manufactured in Example 1 was reacted with succinimidyl 4-maleimido butyrate (SMB) to immobilize linker molecules thereon. For the immobilization, SMB was initially dissolved in a DMF solvent and diluted ten fold with sodium hydrogen carbonate buffer (50 mM, pH 8.5) to a concentration of 20 mM. 3′-SH-15mer-Cy3-5′ was dissolved in a spotting solution (10 mM HEPES, 5 mM EDTA, pH 6.6), followed by an addition of DMSO (40% by volume). The spotting solution mixture was spotted on the substrate on which the linker molecules had been immobilized, using a pin-type spotting instrument for microarrays and left at room temperature and a humidity of 70-75% for 3 hours to manufacture a biochip.

### EXPERIMENTAL EXAMPLE 1

### Thickness and Surface Density Measurements

Before reaction with the aromatic aldehyde compound in the above examples, the thickness of the aminosilyated monolayers and the density of amine groups on the surface of the molecular layer were measured. As a result, the thickness of the molecular layer ranged from 8 Å to 10 Å, and the surface density of amine groups was about 3.5 amines/nm². After the condensation of the aminosilylated monolayer with benzaldehyde and cinnamaldehyde, the thickness increased by 3-5 Å and 4-6 Å, respectively.

### EXPERIMENTAL EXAMPLE 2

### Atomic Fore Microscopic Analysis

The substrate with the pattern manufactured in Example 1 was analyzed using atomic force microscopy (AFM), as shown in FIG. 4. The photograph of FIG. 4 at a scale of 10 μm×10 μm shows a region of the substrate where TEM grid patterns of a 5-μm width intersect. In FIG. 4, outer regions of the intersection appear bright. The bright regions are believed to be higher than the level of the intersection by about 4 Å. In particular, the bright regions were irradiated with electron beams through the TEM grid used as the photomask, so that the imine group therein was transformed into a non-hydrolyzable chemical species, thereby resulting in a hydrophobic surface having aromatic rings. As a result, the height of the irradiated regions was greater than that of the non-irradiated region where the 5-μm grid patterns intersect to shield light, by a degree equal to the dimension of the aromatic ring.

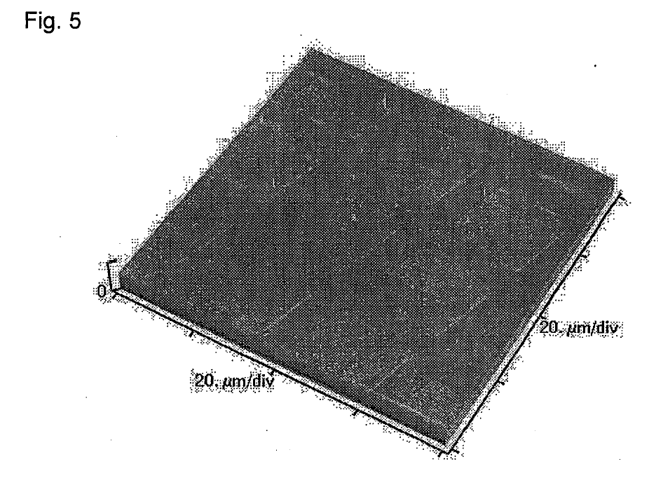

FIG. 5 is a 3-dimensional AFM photograph of an 80 μm×80 μm region of the substrate with the pattern formed in Example 1. Apparently, the original pattern of the TEM grid used as the photomask is perfectly transferred into the self-assembled monolayer on the surface of the silica substrate.

The results of the AFM analysis confirms that surface patterning on a scale of a few nanometers can be achieved using the patterning system according to the present invention with a higher resolution mask.

According to the present invention, a high resolution pattern having alternate hydrophilic and hydrophobic regions can be formed in a desired shape on a surface of a substrate within a short period of time. The substrate with such a high resolution pattern is greatly useful as a base substrate that is accompanied by coating with a copolymer and selective surface etching in the semiconductor material field. Due to the reactive hydrophilic amine groups in the pattern, binding with enzymes or various functional substances can be controlled on a nano-scale. Therefore, the high resolution patterning according to the present invention can greatly contribute to the development of highly-integrated biochips or miniaturized biosensors.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method for high resolution patterning, comprising:
(a) forming an aromatic imine monolayer having a substituted or unsubstituted terminal ring on a substrate;
(b) selectively transforming imine bonds structurally in the aromatic imine molecular layer; and
(c) hydrolyzing the aromatic imine molecular layer.

2. The method of claim 1, wherein (a) forming the aromatic imine monolayer on the substrate comprises:
forming a self-assembled aminosilylated or aminothiolated monolayers on the substrate; and
processing the surface of the self-assembled aminosilylated or aminothiolated monolayers with an aromatic aldehyde having a substituted or unsubstituted terminal ring.

3. The method of claim 2, wherein the aromatic aldehyde having the substituted or unsubstituted terminal ring is a conjugated aromatic aldehyde or a non-conjugated aromatic aldehyde.

4. The method of claim 3, wherein the non-conjugated aromatic aldehyde with the substituted or unsubstituted terminal ring is a compound of formula (1) below: 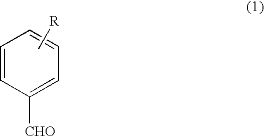
where R is hydrogen atom, a substituted or unsubstituted C₁-C₂₀ alkyl group, a substituted or unsubstituted C₁-C₂₀ alkoxy group, or a substituted or unsubstituted C₆-C₃₀ aryl group.

5. The method of claim 3, wherein the conjugated aromatic aldehyde with the substituted or unsubstituted terminal ring is a compound of formula (2), (3), or (4) below: 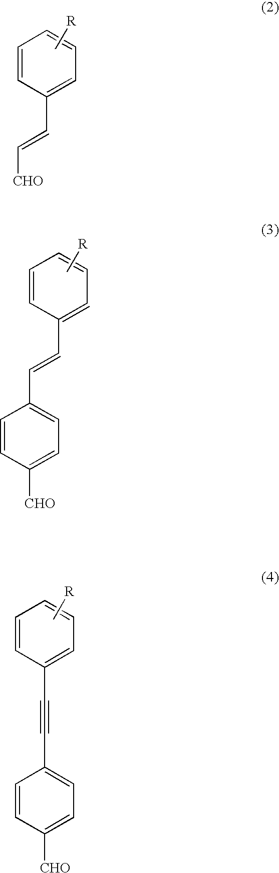
where R is hydrogen atom, a substituted or unsubstituted C₁-C₂₀ alkyl group, a substituted or unsubstituted C₁-C₂₀ alkoxy group, or a substituted or unsubstituted C₆-C₃₀ aryl group.

6. The method of claim 1, wherein the substrate is formed of silica or gold.

7. The method of claim 1, wherein (b) selectively transforming imine bonds structurally in the aromatic imine molecular layer comprises exposing the substrate to a low-energy electron beam through a photomask placed on the substrate.

8. The method of claim 7, wherein the low-energy electron beam has an energy level of 5,000 eV or less.

9. A substrate with a high resolution pattern, the substrate comprising:
a base plate; and
a surface layer on the base plate, the surface layer including a hydrophilic amine monolayer in a region and a hydrophobic aromatic imine monolayer in the other region which form the high pattern together.

10. A method for manufacturing a semiconductor device, the method comprising:
coating a diblock copolymer onto the substrate of claim 9; and
thermally processing and etching the substrate coated with the diblock copolymer.

11. The method of claim 10, wherein the diblock copolymer is poly(stylene-block-methylmethacrylate).

12. A biochip comprising:
the substrate of claim 9; and
biomolecules bound to amine groups of the hydrophilic amine molecular layer.

13. The biochip of claim 12, wherein the biomolecules are proteins, DNA, or RNA.
